(19) United States
(12) Patent Application Publication
(10) Pub. No.: US 2025/0147427 A1
(43) Pub. Date: May 8, 2025

(54) PROJECTION EXPOSURE APPARATUS FOR SEMICONDUCTOR LITHOGRAPHY

(71) Applicant: Carl Zeiss SMT GmbH, Oberkochen (DE)

(72) Inventors: Carlos Alberto JANSEN, Heubach (DE); Alexander FRITZKOWSKI, Gerstetten (DE); Eric VAN RIJEN, Valkenburg aan de Ge ul (NL)

(21) Appl. No.: 19/012,047

(22) Filed: Jan. 7, 2025

Related U.S. Application Data
(63) Continuation of application No. PCT/EP2023/069200, filed on Jul. 11, 2023.

(30) Foreign Application Priority Data
Jul. 13, 2022 (DE) 10 2022 207 148.4

(51) Int. Cl. G03F 7/00

(52) U.S. Cl. CPC G03F 7/70316; G03F 7/70233; G03F 7/70825; G03F 7/70891

(57) ABSTRACT

A projection exposure apparatus has a heating device for heating at least one element of the projection exposure apparatus via electromagnetic radiation. The heating device comprises an illumination optical unit having a housing and at least one optical element, arranged within the housing, for influencing the electromagnetic radiation. The at least one optical element is fixed within the housing by way of at least one elastic element.

### CROSS-REFERENCE TO RELATED APPLICATIONS

The present application is a continuation of, and claims benefit under 35 USC 120 to, international application No. PCT/EP2023/069200, filed Jul. 11, 2023, which claims benefit under 35 USC 119 of German Application No. 10 2022 207 148.4, filed Jul. 13, 2022. The entire disclosure of each of these applications is incorporated by reference herein.

### FIELD

The disclosure relates to a projection exposure apparatus for semiconductor lithography.

### BACKGROUND

In relation to their imaging quality, projection exposure apparatuses for semiconductor lithography can exhibit a behaviour that depends significantly on temperature. Both elements not involved directly in the optical imaging, such as, for example, mounts and holders or housing parts, and optical elements themselves, such as for example lenses or, in the case of EUV lithography, mirrors, typically change their extent or their surface shape when heated up or cooled down, which can have a direct effect on the quality of the imaging of a lithography mask, for example a phase mask, a so-called reticle, on a semiconductor substrate, a so-called wafer, as undertaken by the system. In this case, the heating of the individual components of the apparatus during operation can be traced back to the absorption of some of the radiation which is used to image the reticle onto the wafer. This radiation is produced by a light source, which is referred to as a used light source hereinafter. In the case of EUV lithography, the used light source is often a comparatively complex plasma source, with which a plasma that emits electromagnetic radiation in the desired short-wave frequency ranges is generated via laser irradiation of tin particles.

Projection exposure apparatuses are usually designed for a stationary state during operation, which is to say a state in which no substantial fluctuations in the temperature of apparatus components should be expected over time. Thus, the apparatus or its components are typically preheated, especially following a long down time of the apparatus and the cooling of the components typically connected therewith, which is to say it is desirable to establish a state in which the projection exposure apparatus and its individual components are each set to temperatures that come close to the values attained during operation.

In this respect, known systems, especially in the case of EUV systems, have used preheaters which are used to both time-dependently and spatially variably compensate aberrations caused by surface deformations on account of absorption-induced temperature fluctuations. The idea involves externally heating the material when little or no used radiation is absorbed, and of reducing the external heating power by an extent equal to the heating on account of the absorption of the used radiation during operation.

Some known approaches use infrared radiation in the preheaters, the infrared radiation being influenced by an illumination optical unit in such a way that it can be adjusted in terms of its intensity, for example also in terms of its intensity distribution. The illumination optical unit frequently comprises a collimator for producing approximately parallel radiation from the infrared radiation produced by a laser and comprises a tube for adjusting the beam shape. Certain known preheaters use what are known as screw rings for fixing the individual optical elements within a housing of the illumination optical unit. However, particles of different dimensions, for example of between 3 micrometers (μm) and 100 μm, may arise on account of the friction arising between the thread and the screw rings. This can be undesirable because this can significantly increase the probability of such a particle precipitating on an optical element and being able to lead to a damaging of the optical element, and hence to an outage of the preheaters, on account of the significant absorption of the heating radiation by the particle.

### SUMMARY

The present disclosure to provide a device which eliminates certain disadvantages of known systems.

In an aspect, the disclosure provides a projection exposure apparatus comprising a heating device for heating at least one element of the projection exposure apparatus by means of electromagnetic radiation. In this case, the heating apparatus comprises an illumination optical unit having a housing and at least one optical element, arranged within the housing, for influencing the electromagnetic radiation. According to the disclosure, at least one optical element is fixed within the housing by way of at least one elastic element. As a result of the optical element being fixing according to the disclosure by way of the spring force exerted by the elastic element, it is possible to dispense with screwing of a holding ring. This can help prevent mutually corresponding flanks of threads from sliding on one another as this could lead to a particle exposure of the illumination optical unit.

In this case, the at least one optical element can be arranged in such a way between the elastic element and a receptacle formed in the housing that the elastic element presses the optical element against the receptacle. In other words, the receptacle in this case can serve as an abutment for the spring force exerted on the optical element by the elastic element.

The at least one optical element can be arranged between a first elastic element and a second elastic element. In this case, there is the option of the first elastic element exerting a force on the second elastic element via the optical element. Then, the second elastic element may in turn for example press a further optical element against a receptacle in the housing, and hence fix the optical element in this way.

It is likewise conceivable for the elastic element to be arranged between a first optical element and a second optical element.

Especially in cases where the optical element is the last optical element in the illumination optical unit, it may be desirable for the elastic element to be arranged between the optical element and a holding element. For example, the holding element may be a retaining ring or lid.

In this case, the lid may comprise a lock, for example in the form of a bayonet lock, arranged on an outer surface of the housing. What can be achieved as a result of the lock being arranged on the outer surface of the housing is that a possible particle exposure caused by components of the lock sliding past one another does not reach the interior of the illumination optical unit.

Especially in cases in which a diffractive optical element, for example a diffraction grating, is used as an optical element, it may be desirable for the illumination optical unit to comprise a displacement unit for positioning at least one optical element in a plane perpendicular to the longitudinal axis of the housing. In this case, the optical element may be arranged in a sleeve of the displacement unit.

By way of example, a friction-free mount of the sleeve in the housing can be achieved by virtue of the sleeve being mounted on at least three pins which each have a spherical contact surface on each end, with the ends of the pins opposite the sleeve resting on a receptacle in the housing of the illumination optical unit. Additionally, or in an alternative thereto, it is also conceivable to use leaf springs or a monolithic kinematic system.

In a variant of the disclosure, the heating device may comprise a labyrinth seal. In this case, the labyrinth seal may be formed by two mutually corresponding partial geometries in two different component parts of the illumination optical unit.

### BRIEF DESCRIPTION OF THE DRAWINGS

Exemplary embodiments and variants of the disclosure will be explained in more detail hereinafter with reference to the drawing, in which:

FIG. 1 schematically shows a meridional section of a projection exposure apparatus for EUV projection lithography;

FIG. 2 schematically shows a meridional section of a projection exposure apparatus for DUV projection lithography;

FIG. 3 shows a known heating device;

FIG. 4 shows a schematic illustration of a heating device according to the disclosure;

FIG. 5 shows a detail view of the disclosure;

FIG. 6 shows a further embodiment of the disclosure;

FIGS. 7A and 7B show a further detail view of the disclosure; and

FIG. 8 shows a further detail view of the disclosure.

### DETAILED DESCRIPTION

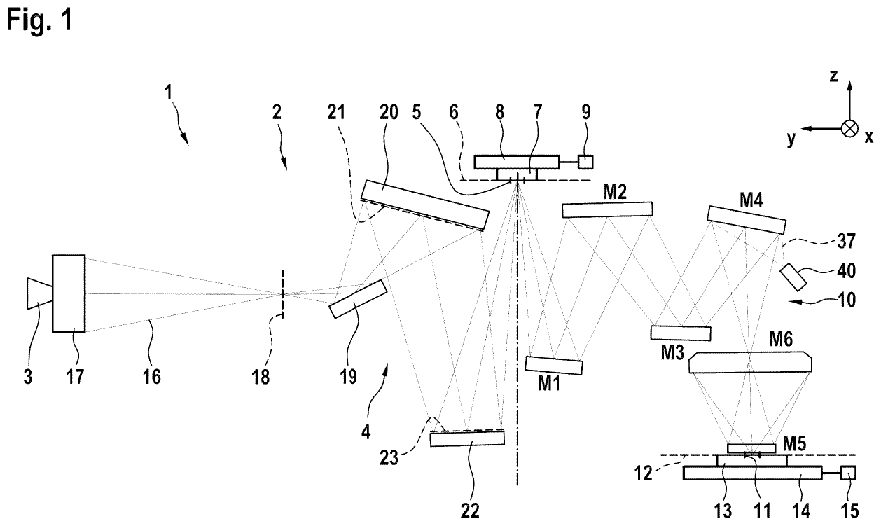

Certain parts of a microlithographic projection exposure apparatus 1 are described in exemplary fashion below initially with reference to FIG. 1. The description of the basic structure of the projection exposure apparatus 1 and its component parts are understood here to be non-limiting.

An embodiment of an illumination system 2 of the projection exposure apparatus 1 has, in addition to a radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable, for example in a scanning direction, by way of a reticle displacement drive 9.

A Cartesian xyz-coordinate system is shown in FIG. 1 for explanation purposes. The x-direction runs perpendicular to the plane of the drawing into the latter. The y-direction runs horizontally, and the z-direction runs vertically. The scanning direction runs in the y-direction in FIG. 1. The z-direction runs perpendicular to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example longitudinally with respect to the y-direction. The displacement, firstly, of the reticle 7 by way of the reticle displacement drive 9 and, secondly, of the wafer 13 by way of the wafer displacement drive 15 can be implemented so as to be mutually synchronized.

The radiation source 3 is an EUV radiation source. The radiation source 3 emits EUV radiation 16, which is also referred to below as used radiation, illumination radiation or illumination light. For example, the used radiation has a wavelength in the range between 5 nm and 30 nm. The radiation source 3 can be a plasma source, for example an LPP (laser produced plasma) source or a GDPP (gas discharge produced plasma) source. It may also be a synchrotron-based radiation source. The radiation source 3 may be a free electron laser (FEL).

The illumination radiation 16 emerging from the radiation source 3 is focused by a collector 17. The collector 17 may be a collector with one or more ellipsoidal and/or hyperboloidal reflection surfaces. The illumination radiation 16 can be incident on the at least one reflection surface of the collector 17 with grazing incidence (GI), which is to say at angles of incidence of greater than 45° relative to the direction of the normal to the mirror surface, or with normal incidence (NI), which is to say at angles of incidence of less than 45°. The collector 17 can be structured and/or coated firstly for optimizing its reflectivity for the used radiation and secondly for suppressing extraneous light.

Downstream of the collector 17, the illumination radiation 16 propagates through an intermediate focus in an intermediate focal plane 18. The intermediate focal plane 18 can represent a separation between a radiation source module, having the radiation source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond a pure deflection effect. As an alternative or in addition, the deflection mirror 19 may be in the form of a spectral filter that separates a used light wavelength of the illumination radiation 16 from stray light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which are also referred to below as field facets. FIG. 1 depicts only some of the facets 21 by way of example.

The first facets 21 may be embodied as macroscopic facets, such as rectangular facets or as facets with an arcuate edge contour or an edge contour of part of a circle. The first facets 21 may be in the form of plane facets or alternatively as facets with convex or concave curvature.

As is known for example from DE 10 2008 009 600 A1, the first facets 21 themselves can also each be composed of a multiplicity of individual mirrors, such as a multiplicity of micromirrors. The first facet mirror 20 may be in the form of a microelectromechanical system (MEMS system). For details, reference is made to DE 10 2008 009 600 A1.

The illumination radiation 16 travels horizontally, which is to say in the y-direction, between the collector 17 and the deflection mirror 19.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or hexagonal boundary, or may alternatively be facets composed of micromirrors. In this regard, reference is likewise made to DE 10 2008 009 600 A1.

The second facets 23 may have plane reflection surfaces or alternatively reflection surfaces with a convex or concave curvature.

The illumination optical unit 4 consequently forms a double-faceted system. This fundamental principle is also referred to as a fly's eye condenser (fly's eye integrator).

It can be desirable to arrange the second facet mirror 22 not exactly in a plane that is optically conjugate to a pupil plane of the projection optical unit 10. For example, the pupil facet mirror 22 can be arranged so as to be tilted relative to a pupil plane of the projection optical unit 10, as is described, for example, in DE 10 2017 220 586 A1.

The individual first facets 21 are imaged into the object field 5 using the second facet mirror 22. The second facet mirror 22 is the last beam-shaping mirror or indeed the last mirror for the illumination radiation 16 in the beam path upstream of the object field 5.

In a further embodiment, not illustrated, of the illumination optical unit 4, a transfer optical unit can be arranged in the beam path between the second facet mirror 22 and the object field 5, the transfer optical unit contributing for example to the imaging of the first facets 21 into the object field 5. The transfer optical unit may comprise exactly one mirror, but alternatively also comprise two or more mirrors, which are arranged one behind the other in the beam path of the illumination optical unit 4. The transmission optical unit can comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20, and the pupil facet mirror 22.

The deflection mirror 19 can also be dispensed with in a further embodiment of the illumination optical unit 4, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is often only approximate imaging.

The projection optical unit 10 comprises a plurality of mirrors Mx, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mx are likewise possible. As illustrated in exemplary fashion using mirror M4 in FIG. 1, at least one of the mirrors Mx can be preheated by heating radiation 37 generated by the heating device 40 according to the disclosure, as a result of which the mirrors Mx can each be set to temperatures that come close to the values attained during operation. Additionally, the heating device 40 can be used for heating during operation, which is to say heat the mirror Mx using the heating device 40 whenever little or no used radiation is absorbed and reduce the external heating power by an extent equal to the heating on account of the absorption of the used radiation during operation. The penultimate mirror M5 and the last mirror M6 each have a passage opening for the illumination radiation 16. The projection optical unit 10 is a doubly obscured optical unit. The projection optical unit 10 has an image-side numerical aperture which is greater than 0.5 and which can also be greater than 0.6 and, for example, can be 0.7 or 0.75.

Reflection surfaces of the mirrors Mx can be in the form of free-form surfaces without an axis of rotational symmetry. Alternatively, the reflection surfaces of the mirrors Mx can be designed as aspherical surfaces with exactly one axis of rotational symmetry of the reflection surface shape. Just like the mirrors of the illumination optical unit 4, the mirrors Mx can have highly reflective coatings for the illumination radiation 16. These coatings can be designed as multilayer coatings, for example with alternating layers of molybdenum and silicon.

The projection optical unit 10 has a large object-image offset in the y-direction between a y-coordinate of a centre of the object field 5 and a y-coordinate of the centre of the image field 11.

In the y-direction, this object-image offset can be of approximately the same magnitude as a z-distance between the object plane 6 and the image plane 12.

The projection optical unit 10 may have an anamorphic form. For example, it has different imaging scales βx, βy in the x- and y-directions. The two imaging scales βx, βy of the projection optical unit 10 are preferably (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction, which is to say in a direction perpendicular to the scanning direction.

The projection optical unit 10 leads to a reduction in size of 8:1 in the y-direction, which is to say in the scanning direction.

Other imaging scales are likewise possible. Imaging scales with the same signs and the same absolute values in the x-direction and y-direction are also possible, for example with absolute values of 0.125 or 0.25.

The number of intermediate image planes in the x-direction and in the y-direction in the beam path between the object field 5 and the image field 11 can be the same or can differ depending on the embodiment of the projection optical unit 10. Examples of projection optical units with different numbers of such intermediate images in the x and y directions are known from US 2018/0074303 A1.

In each case one of the pupil facets 23 is assigned to exactly one of the field facets 21 to form a respective illumination channel for illuminating the object field 5. For example, this can yield illumination according to the Köhler principle. The far field is decomposed into a multiplicity of object fields 5 with the aid of the field facets 21. The field facets 21 generate a plurality of images of the intermediate focus on the pupil facets 23 respectively assigned thereto.

The field facets 21 are imaged, in each case by way of an assigned pupil facet 23, onto the reticle 7 in a manner such that they are superposed on one another for the purposes of illuminating the object field 5. The illumination of the object field 5 is in general as homogeneous as possible. It preferably has a uniformity error of less than 2%. The field uniformity can be achieved by overlaying different illumination channels.

The illumination of the entrance pupil of the projection optical unit 10 can be geometrically defined by an arrangement of the pupil facets. It is possible to set the intensity distribution in the entrance pupil of the projection optical unit 10 by selecting the illumination channels, for example the subset of pupil facets, which guide light. This intensity distribution is also referred to as illumination setting.

A likewise preferred pupil uniformity in the region of sections of an illumination pupil of the illumination optical unit 4 that are illuminated in a defined manner can be achieved by a redistribution of the illumination channels.

Further aspects and details of the illumination of the object field 5 and for example of the entrance pupil of the projection optical unit 10 are described below.

The projection optical unit 10 may have a homocentric entrance pupil. The latter can be accessible. It can also be inaccessible.

The entrance pupil of the projection optical unit 10 generally cannot be illuminated exactly via the pupil facet mirror 22. The aperture rays often do not intersect at a single point when imaging the projection optical unit 10 which telecentrically images the centre of the pupil facet mirror 22 onto the wafer 13. However, it is possible to find a surface area in which the spacing of the aperture rays, determined in pairwise fashion, is minimal. This surface area represents the entrance pupil or an area in real space that is conjugate thereto. For example, this surface area has a finite curvature.

The projection optical unit 10 might have different positions of the entrance pupil for the tangential beam path and for the sagittal beam path. In this case, an imaging element, for example an optical component part of the transfer optical unit, should be provided between the second facet mirror 22 and the reticle 7. With the aid of this optical element, the different poses of the tangential entrance pupil and the sagittal entrance pupil can be taken into account. In the arrangement of the components of the illumination optical unit 4 illustrated in FIG. 1, the pupil facet mirror 22 is arranged in an area conjugate to the entrance pupil of the projection optical unit 10. The field facet mirror 20 is tilted with respect to the object plane 6. The first facet mirror 20 is tilted with respect to an arrangement plane defined by the deflection mirror 19.

The first facet mirror 20 is tilted with respect to an arrangement plane defined by the second facet mirror 22.

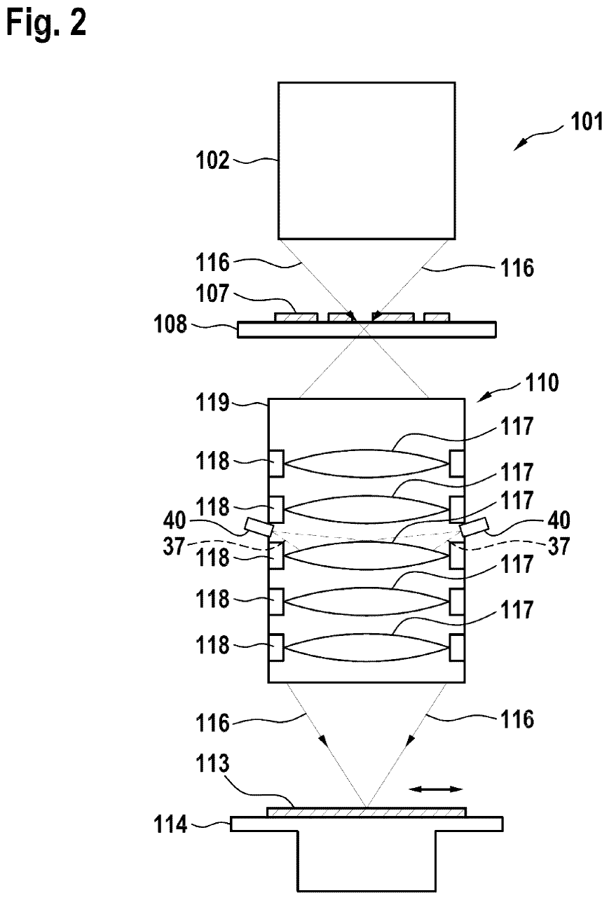

FIG. 2 schematically shows a meridional section through a further projection exposure apparatus 101 for DUV projection lithography, in which the disclosure can likewise be used.

The structure of the projection exposure apparatus 101 and the principle of the imaging are comparable with the structure and procedure described in FIG. 1. Identical component parts are denoted by a reference sign increased by 100 relative to FIG. 1, which is to say the reference signs in FIG. 2 begin with 101.

In contrast to an EUV projection exposure apparatus 1 as described in FIG. 1, refractive, diffractive and/or reflective optical elements 117, such as for example lens elements, mirrors, prisms, terminating plates, and the like, can be used for imaging or for illumination in the DUV projection exposure apparatus 101 on account of the greater wavelength of the DUV radiation 116, employed as used light, in the range from 100 nm to 300 nm, for example of 193 nm. The projection exposure apparatus 101 in this case comprises an illumination system 102, a reticle holder 108 for receiving and exactly positioning a reticle 107 provided with a structure, which determines the later structures on a wafer 113, a wafer holder 114 for holding, moving, and exactly positioning the wafer 113, and a projection lens 110, with a plurality of optical elements 117, which are held by way of mounts 118 in a lens housing 119 of the projection lens 110. At least one of the optical elements 117 can be heated by heating radiation 37 produced by a heating device 40, the function of which was already explained on the basis of FIG. 1.

The illumination system 102 provides DUV radiation 116 for imaging the reticle 107 on the wafer 113. A laser, a plasma source or the like can be used as the source of this radiation 116. The radiation 116 is shaped in the illumination system 102 via optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the structure of the downstream projection optical unit 110 with the lens housing 119 does not differ in principle from the structure described in FIG. 1 and is therefore not described in further detail.

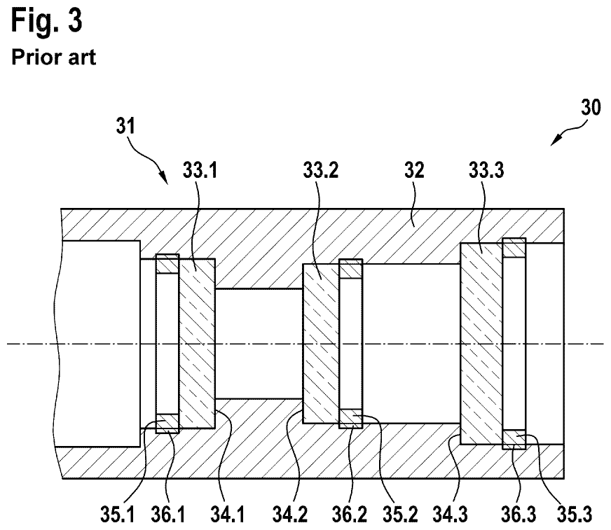

FIG. 3 shows a schematic illustration of a detail of a heating device 30 known from the prior art, in which a housing 32 of an illumination optical unit 31 of the heating device 30 is depicted. The housing 32 comprises a plurality of optical elements 33.1, 33.2, 33.3, which respectively rest on a receptacle 34.1, 34.2, 34.3 formed in the housing 32. The optical elements 33.1, 33.2, 33.3 are each fixed vis-à-vis the receptacle 34.1, 34.2, 34.3 by way of a holding ring 35.1, 35.2, 35.3, which is screwed into the housing 32 by way of a thread 36.1, 36.2, 36.3 arranged therein. Screwing the holding rings 35.1, 35.2, 35.3 into the housing 32 may create particles which can precipitate on the optical elements 33.1, 33.2, 33.3. As a result, the optical elements 33.1, 33.2, 33.3 may be damaged when the illumination optical unit 32 is exposed to heating radiation (not illustrated here) on account of the absorption of the heating radiation by the particles, and therefore the illumination optical unit 31, and hence the heating device 30, may suffer an outage.

It is self-evident that the optical unit shown in the figure should be understood to be purely exemplary. The principle shown may also be applied to other optical arrangements, for example collimators.

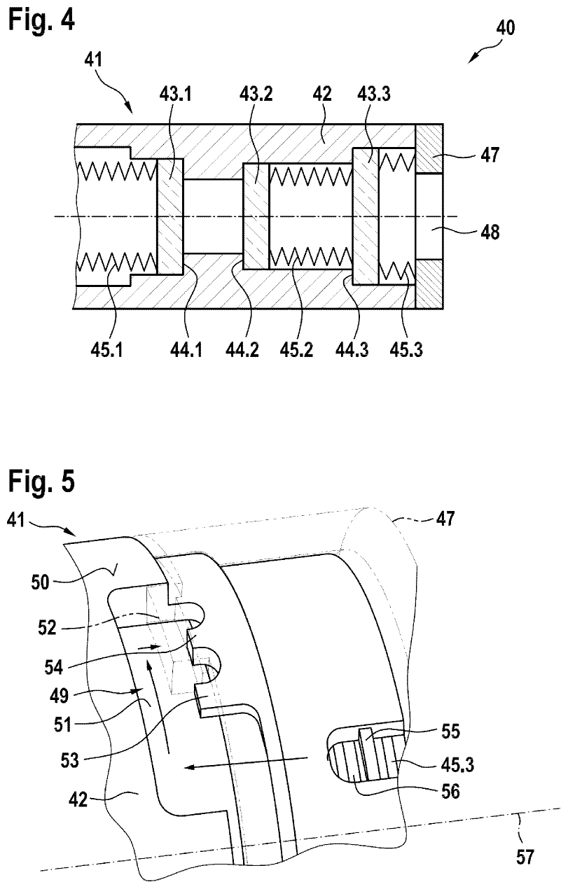

In a schematic illustration, FIG. 4 shows a detail of a heating device 40 according to the disclosure, having a housing 42 of an illumination optical unit 41. The housing 42 accommodates a plurality of optical elements 43.1, 43.2, 43.3, which respectively are arranged on a receptacle 44.1, 44.2, 44.3 formed in the housing 42. The optical elements 43.1, 43.2, 43.3 are pressed against the receptacles 44.1, 44.2, 44.3 by elastic elements in the form of springs 45.1, 45.2, 45.3, as result of which the optical elements 43.1, 43.2, 43.3 are fixed within the housing 42. The spring 45.2 for fixing the optical element 43.2 illustrated in the centre of FIG. 4 is in this case supported on the adjacent optical element 43.3, which is to say uses the optical element 43.3 as an abutment. In turn, the optical element 43.3 is pressed by way of the spring 45.3 against the receptacle 44.3 formed in the housing 42 and is fixed as a result. The spring 45.3 is supported by a lid 47 which closes the housing 42, the lid 47 having an opening 48 for the passage of the heating radiation (not illustrated here). In addition to fixing the optical element 43.3, the spring 45.3 also causes the lid 47 to be securely connected to the housing 42 by way of a bayonet lock 49 which is explained in detail in FIG. 5. As a result of arranging the bayonet lock 49 on the outer surface 50 of the housing 42, particles possibly created during the closing process can be prevented from reaching the interior of the housing 42 and hence from reaching one of the optical elements 43.1, 43.2, 43.3.

FIG. 5 shows a detail of the heating device 40, in which the bayonet lock 49 of the lid 47 of the housing 42 is illustrated, the lid 47 being illustrated transparently in FIG. 5. A cutout 51, into which a corresponding extension 52 formed on the outer edge of the lid 47 can be dipped, is formed in the outer surface 50 of the housing 42. In this case, the cutout 41 comprises a first stop 53, with the aid of which a rotation of the lid 47, and hence an inadvertent opening of the lid 47, is prevented once the lid 47 has been closed. To close the lid 47, the latter is placed on the housing 42 in such a way that the extension 52 on one side of the stop 43 can be dipped into a corresponding part of the cutout 51. Subsequently, the lid 47 is pressed against the spring 45.3, which has already been explained on the basis of FIG. 4, in the direction of the longitudinal axis 57 of the housing 42, and as a result is dipped deeper into the first part of the cutout 51 in the direction of the longitudinal axis 57. The extension 52 of the lid 47 is now rotated to the opposite end of the cutout 51 by way of a rotation of the lid 47 below the stop 53. When the lid 47 is released, the extension 52, as a result of the spring force exerted by the spring 45.3, dips as far as a second stop 54, which is formed in a second corresponding part of the cutout 51, in this part of the cutout 51 and is fixed against the second stop by the spring force. A rotation of the extension 52 in this position is prevented by the end of the cutout 51 on one side and the stop 53 on the other side. The spring 45.3 comprises a lug 55, which is directed outwardly in the direction of the housing 42 and which, in the assembled state, is arranged in a recess 56 formed in the housing 42. This prevents the spring 45.3 from rotating with the lid 47 when the lid 47 is closed or opened. As a result of arranging the bayonet lock 49 on the outer surface 50 of the housing 42, particles possibly created during the closing or opening process of the lid 47 cannot reach the interior of the housing 42 and hence the optical elements 43.1, 43.2, 43.3.

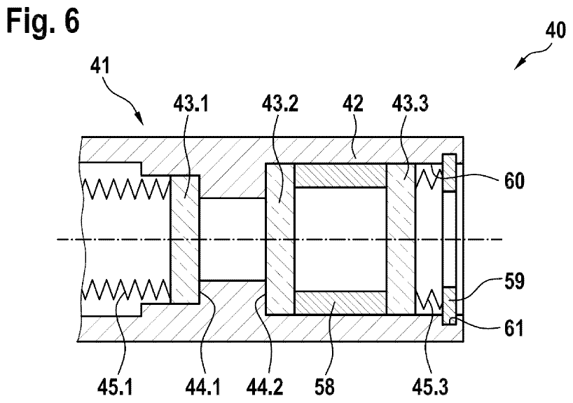

FIG. 6 shows a further embodiment of the disclosure, in which a housing 42 of the illumination optical unit 41 of a heating device 40 is illustrated. The housing 42 comprises a plurality of optical elements 43.1, 43.2, 43.3. As already explained in FIG. 4, the first optical element 43.1, depicted on the left-hand side of FIG. 6, is fixed against a receptacle 44.1 by way of a spring of 45.1. The second optical element 42.3 likewise rests on a receptacle 44.2 on one side. A solid sleeve 58 is arranged on the other side of the optical element 43.2. It firstly defines the distance between the second 43.2 and the third optical element 43.3 and secondly transmits the force of the spring 45.3, with the aid of which the second optical element 43.2 is fixed against the receptacle 44.2. The spring 45.3 is held by a holding ring 59, for example a circlip, which is assembled in a groove 61 formed in the inner side 60 of the housing 42 and as a result fixes the optical element 43.3 against the sleeve 59.

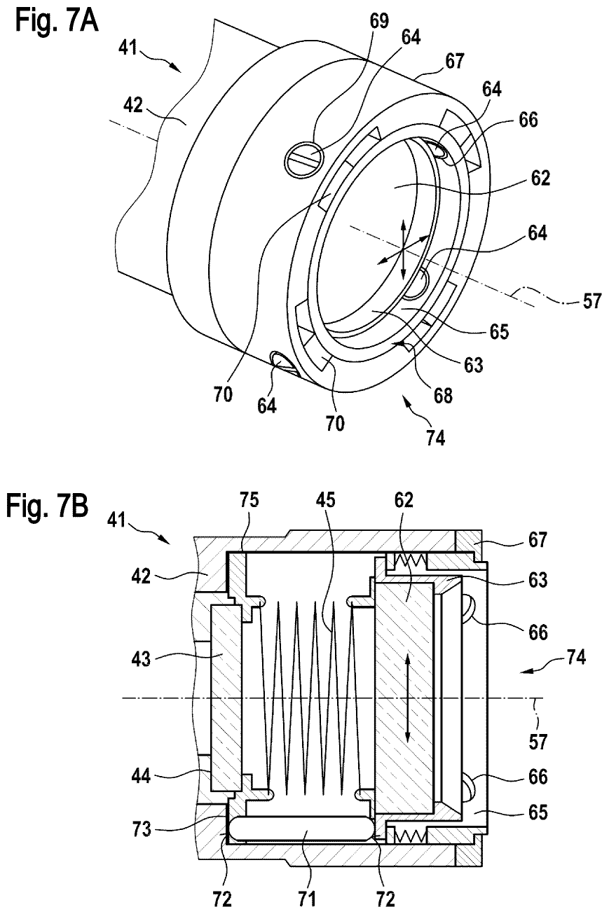

FIG. 7A shows a further detailed view of the disclosure, in which one side of the housing 42 of the illumination optical unit 41 with a displacement unit 74 is illustrated. The displacement unit 74 comprises a sleeve 63, in which an optical termination element 62 arranged in the housing 42 is held. The sleeve 63 is mounted in such a way that the termination element 62 can be positioned in an X-Y-plane perpendicular to the longitudinal axis 57 of the housing 42 by way of four setscrews 64 of the displacement unit 74, as indicated in FIG. 7A by two double-headed arrows. The setscrews 64 are each guided by way of a thread (not illustrated here) in a flange 70 of the housing 42 and can be adjusted by rotation. A spring 65, which fixes the sleeve 63 and hence the optical termination element 62, as already explained above, in the housing 42 is connected to the housing 42 by a lid 67. Both the lid 67 and the spring 65 have holes 69, 66 for the setscrews 64.

FIG. 7B shows a sectional illustration through the end of the housing 42 with the displacement unit 74 shown in FIG. 7A. The sleeve 63 is mounted on three pins 71, which each have a spherical contact surface 72 on both ends. The ends of the pins 71 opposite to the sleeve 63 rest on a receptacle 73 in the housing 42 of the illumination optical unit 41. The pins 71 roll on the receptacle 73 or on the sleeve 63 as a result of their spherical contact surfaces 72 in the case of a movement of the sleeve 63 in the X-Y-plane, as a result of which a friction-free and hence particle-free movement of the sleeve 63 in the X-Y-plane is ensured. A fine adjustment of the corresponding optical element can be achieved by way of the movement of the sleeve 63. An elastic element in the form of the spring 45 is arranged in turn between the sleeve 63 of the optical termination element 62 and the next optical element 43 and fixes the optical element 43 against a further receptacle 44 in the housing 42. The spring 45 is designed so that the end of the spring 45 directed toward the optical termination element 62 can carry out a movement of +/−0.25 mm in the X-Y-plane perpendicular to the longitudinal axis 57 of the housing 42. The opposite end of the spring 45 is prevented from moving in the X-Y-plane by way of a guide 75 formed radially within the housing 42, as a result of which a movement of the lower part of the spring 45 on the optical element 43 and the possible generation of particles connected therewith can be avoided. Alternatively, the sleeve 63 can also be mounted on leaf springs or another type of friction-free, for example monolithically designed mount.

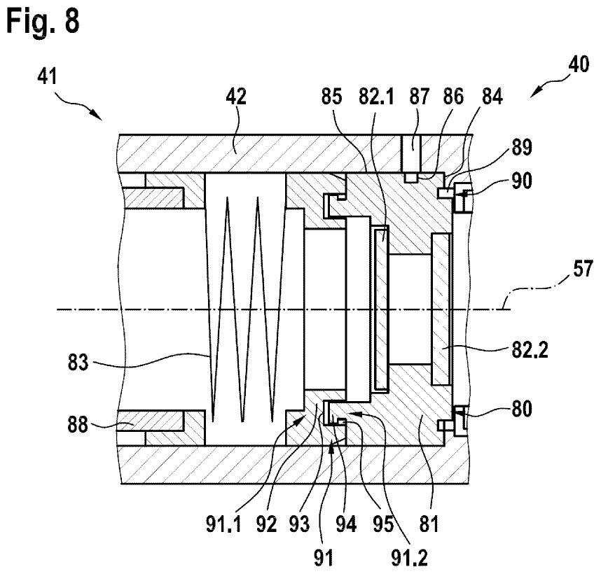

FIG. 8 shows a further detailed view of an illumination optical unit 41 of a heating device 40, in which a housing 42 with a rotation unit 80 is illustrated. In the embodiment explained in FIG. 8, the rotation unit 80 comprises a holder 81 for two optical elements, for example in the form of diffractive optical elements 82.1, 82.2. In the embodiment illustrated in FIG. 8, the holder 81 is pressed by way of an elastic element in the form of a spring 83 against a stop 84 formed in the housing 42, and is radially guided on its outer side via a guide 85 formed in the housing 42. The holder 81 can be rotated about the longitudinal axis 57 of the housing 42 by way of a depression 86 formed on the outer side of the holder 81. The depression 86 is accessible to a tool (not illustrated here) via an access 87, for example in the form of a slot, formed in the housing 42, with the result that the holder 81 can only be rotated for the purpose of adjusting the spatial distribution of the heating radiation (not illustrated here). The spring 83 is prestressed on the side opposite the rotation unit 80 by way of a sleeve 88, which for example is fixed via a holding ring 59 (not illustrated here) as explained in FIG. 6 or a lid 47, 67 (not illustrated here) as explained in FIG. 4, 5 or 7A, 7B. The holder 81 of the rotation unit 80 comprises a labyrinth seal 90, 91 on both sides. The latter prevents particles generated during the rotation of the holder 81 at the stop 84 or the guide 85 from being dragged into the interior and hence into the region of the optical elements 82.1, 82.2. On the side of the holder 81 depicted to the right of FIG. 8, the labyrinth seal 90 is formed as an axial furrow 89 in the end side of the holder 81. On the opposite side of the holder 81, the labyrinth seal 91 is formed by a first partial geometry 91.1 in the spring 83 and a corresponding second partial geometry 91.2 in the holder 81. The first partial geometry 91.1 is formed as a depression 93 running in a flange 92 of the spring 83 on an end side. The second partial geometry 91.2 is formed as a circumferential web 94 which is arranged on the end face of the holder 81 facing the spring 83 and which projects into the depression 93 in the spring 83. The web 94 additionally comprises a circumferential puncture 93 formed on its outer side.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Heating device
31 Illumination optical unit
32 Housing
33.1-33.3 Optical element
34.1-34.3 Receptacle
35.1-35.3 Holding ring
36.1-36.3 Thread
37 Heating radiation
40 Heating device
41 Illumination optical unit
42 Housing
43.1-43.3 Optical element
44.1-44.3 Receptacle
45.1-45.3 Spring
47 Lid
48 Opening
49 Bayonet lock
50 Outer surface
51 Cutout for the extension
52 Extension
53 Extension rotation stop
54 Extension translation stop
55 Lug
56 Recess
57 Longitudinal axis of the housing
58 Sleeve
59 Holding ring
60 Inner side of the housing
61 Groove
62 Optical termination element
63 Sleeve
64 Setscrew
65 Spring
66 Hole in the spring
67 Lid
68 Opening of the lid
69 Hole in the lid
70 Flange to receive the setscrew
71 Stiff
72 Spherical contact surface
73 Receptacle for pins
74 Displacement unit
75 Guide
80 Rotation unit
81 Mount
82.1, 82.2 Optical elements
83 Spring
84 Stop
85 Guide
86 Depression
87 Access
88 Sleeve
89 Furrow
90 Labyrinth seal
91, 91.1, 91.2 Labyrinth seal, partial geometries
92 Flange
93 Puncture
94 Web
95 Puncture
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing
M1-M6 Mirrors

What is claimed is:

1. A projection exposure apparatus, comprising:
an element;
a heating device configured to heat the element via electromagnetic radiation, the heating device comprising an illumination optical unit, the illumination optical unit comprising:
a housing;
a first optical element; and
a first elastic element fixing the optical element within the housing,
wherein the optical element is configured to influence the electromagnetic radiation.

2. The projection exposure apparatus of claim 1, wherein the illumination optical unit comprises a second optical element, and the first elastic element fixes the second optical element within the housing.

3. The projection exposure apparatus of claim 2, wherein the illumination optical unit is configured so that a spring force exerted by the first elastic element is transmitted along a direction of a longitudinal axis of the housing of the heating device.

4. The projection exposure apparatus of claim 3, wherein the illumination unit further comprises a second elastic element between the first and second optical elements, wherein the spring force is transmitted to the first optical element via the second optical element and the second elastic element.

5. The projection exposure apparatus of claim 3, wherein the illumination unit further comprises a solid sleeve between the first and second optical elements, wherein the spring force is transmitted to the first optical element via the second optical element and the solid sleeve.

6. The projection exposure apparatus of claim 1, wherein a receptacle is formed in the housing, and the first elastic element presses the first optical element against the receptacle.

7. The projection exposure apparatus of claim 1, wherein the illumination unit further comprises a second elastic element, wherein the first optical element is between the first and second elastic elements.

8. The projection exposure apparatus of claim 1, wherein the illumination unit further comprises a second optical element, wherein the first elastic element is between the first and second optical elements.

9. The projection exposure apparatus of claim 1, wherein the illumination unit further comprises a holding element, wherein the first elastic element is between the first optical element and the holding element.

10. The projection exposure apparatus of claim 9, wherein the holding element comprises a retaining ring or a lid.

11. The projection exposure apparatus of claim 9, wherein the holding element comprises a lid, and the lid comprises a lock on an outer surface of the housing.

12. The projection exposure apparatus of claim 11, wherein the lock comprises a bayonet lock.

13. The projection exposure apparatus of claim 1, wherein the illumination optical unit further comprises a displacement unit configured to position the first optical element in a plane perpendicular to a longitudinal axis of the housing.

14. The projection exposure apparatus of claim 13, wherein the displacement unit comprises a sleeve, and the first optical element is arranged in the sleeve.

15. The projection exposure apparatus of claim 14, wherein the sleeve is mounted without friction in the housing.

16. The projection exposure apparatus of claim 15, wherein the sleeve is mounted on three pins, each pin has a spherical contact surface at either end, and the ends of the pins opposite the sleeve rest on a receptacle in the housing.

17. The projection exposure apparatus of claim 1, wherein the heating device comprises a labyrinth seal.

18. The projection exposure apparatus of claim 17, wherein the labyrinth seal is defined by two mutually corresponding partial geometries in two different component parts of the illumination optical unit.

19. The projection exposure apparatus of claim 1, wherein the projection exposure apparatus comprises a projection lens configured to project an illuminated object in an object field into an image field, and the element is an element of the projection lens.

20. The projection exposure apparatus of claim 19, wherein the element comprises a mirror or a lens.
